(19) United States
(12) Patent Application Publication
(10) Pub. No.: US 2025/0079131 A1
(43) Pub. Date: Mar. 6, 2025

(54) STRUCTURAL MEMBER

(71) Applicant: TOTO LTD., Fukuoka (JP)

(72) Inventors: Yasutaka NITTA, Fukuoka (JP); Ryoto TAKIZAWA, Fukuoka (JP); Susumu ADACHI, Fukuoka (JP); Atsushi KINJO, Fukuoka (JP); Tatsuya KOGA, Fukuoka (JP)

(73) Assignee: TOTO LTD., Fukuoka (JP)

(21) Appl. No.: 18/819,886

(22) Filed: Aug. 29, 2024

(30) Foreign Application Priority Data
Aug. 31, 2023 (JP) 2023-141168

(51) Int. Cl. H01J 37/32

(52) U.S. Cl. CPC H01J 37/32495; H01J 2237/334

(57) ABSTRACT

A structural member 10 includes a base material 100 and a protective film 200 covering a surface 101 of the base material 100. At least a portion of the protective film 200 in the vicinity of a surface 201 thereof has a first layer 210 and a second layer 220 that contains all of elements contained in the first layer 210 and that is different from the first layer 210 in composition ratio of each element, wherein the first layer 210 and the second layer 220 are alternately aligned along a depth direction perpendicular to the surface 201 of the protective film 200.

### CROSS-REFERENCE TO RELATED APPLICATION

This application is based upon and claims the benefit of priority from Japanese Patent Application No. 2023-141168 filed on Aug. 31, 2023, the entire contents of which are incorporated herein by reference.

### BACKGROUND

### Field of the Invention

The present invention relates to a structural member.

### Description of the Related Art

Structural members having a protective film on a surface of a base material are used in various fields such as semiconductor manufacturing apparatus. For example, as described in Japanese Patent Laid-Open No. 2007-321183, in a semiconductor manufacturing apparatus, a protective film is formed on a surface of a base material constituting an inner wall of a chamber in order to protect the base material from plasma. As such a protective film, for example, an oxide ceramic such as yttria is used.

When the protective film is exposed to plasma, a surface layer portion of the protective film is eroded by the plasma and is gradually deteriorated. After a certain period of time has elapsed, the deteriorated portion on the surface layer of the protective film is removed by polishing or the like to expose a new, undeteriorated surface, thereby allowing the structural member to continue to be used.

### SUMMARY

The depth of the deteriorated portion of the protective film is not uniform within the plane thereof and varies from place to place. Therefore, when removing a surface layer of the protective film by polishing or the like, it is necessary to set the amount of removal according to the most deeply deteriorated portion. For other portions, an undeteriorated portion of the protective film is also removed. Moreover, since the protective film is removed to a deep position thereof each time, the protective film is made thin in a relatively short period of time, thereby necessitating exchange of the structural member to a new member.

The present invention was made in view of these problems, and an object of the present invention is to provide a structural member capable of being used over a long period of time.

In order to solve the above problem, the structural member according to the present invention includes a base material and a protective film covering a surface of the base material. At least a portion of the protective film in the vicinity of a surface thereof has a first layer and a second layer that contains all of elements contained in the first layer and that is different from the first layer in composition ratio of each element, wherein the first layer and the second layer are alternately aligned along a depth direction perpendicular to the surface of the protective film.

In such a structural member, at least a portion of the protective film in the vicinity of the surface thereof has a multilayer structure, with the first layer and second layer alternately aligned. In such a configuration, deterioration of the protective film is likely to proceed in a direction parallel to an interface of each layer than in the depth direction. As the deterioration proceeds more slowly in the depth direction, a surface layer of the protective film can be less frequently removed, so that the structural member can be used over a long period of time.

Accompanying the deterioration proceeding slowly toward the depth direction, an in-plane variation in depth of the deteriorated portion also becomes smaller. It is then not necessary for the protective film to be removed to a deep position each time, thereby enabling use of the structural member over an even longer period of time.

According to the present invention, it is possible to provide a structural member that can be used over a long period of time.

### BRIEF DESCRIPTION OF THE DRAWINGS

FIG. 1 shows a schematical diagram of a cross-section of the structural member according to the present embodiment;

FIG. 2 shows a diagram of an enlarged view of configuration of a portion A in FIG. 1;

FIG. 3A and FIG. 3B show diagrams for explaining deterioration of a protective film; and

FIGS. 4A to 4D show a diagram for explaining the method for producing a structural member according to the present embodiment.

### DETAILED DESCRIPTION

The present embodiment will be described by referring to the attached drawings. In order to facilitate understanding of the description, an identical constituent is indicated with the same sign as far as possible in each drawing, and duplicated explanations will be omitted.

A structural member 10 according to the present embodiment is used as a member constituting an inner wall of a processing chamber in a semiconductor manufacturing apparatus (not shown), for example, such as a plasma etching apparatus. Note, however, that the application of such structural member 10 is only an example, and should not be limited to the semiconductor manufacturing apparatus.

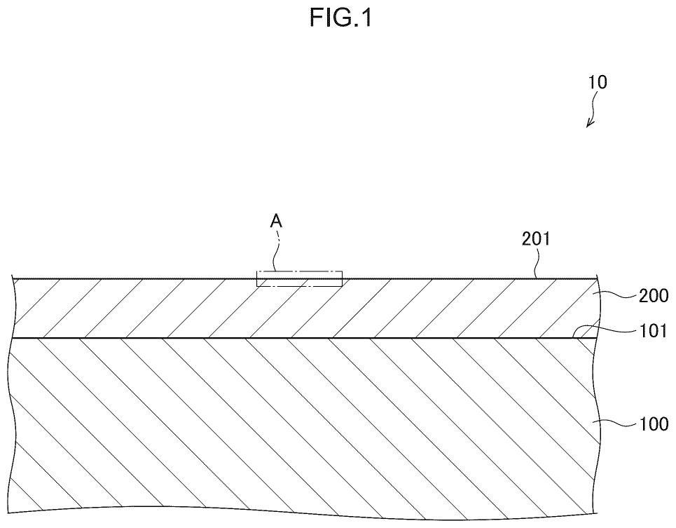

As shown in FIG. 1, the structural member 10 includes a base material 100 and a protective film 200. In a plasma etching apparatus and the like, a surface 201 of the protective film 200 is exposed toward a space in the chamber. The protective film 200 is arranged for the purpose of protecting a surface 101 of the base material 100 from plasma.

The base material 100 is a member that mostly occupies the entire structural member 10. In the present embodiment, the base material 100 is composed of a sintered ceramic body containing high-purity aluminum oxide (Al2O3), but may be made of a different type of ceramic or a member other than a ceramic (for example, a metal member). The surface 101 of the base material 100 is a flat surface in the present embodiment, but the surface 101 may have a convex and concave structure, a slope, or the like.

As described before, the protective film 200 is a film formed to protect the base material 100 against plasma. The protective film 200 is formed so as to cover the entire surface 101 of the base material 100. The protective film 200 is a film containing polycrystalline yttrium oxide. The protective film 200 is formed using a physical vapor deposition (PVD) method. Specific formation method will be explained below. A thickness of the protective film 200 is appropriately set depending on a length of period of time required to maintain durability or the like. In the present embodiment, the protective film 200 has a thickness of 10 μm.

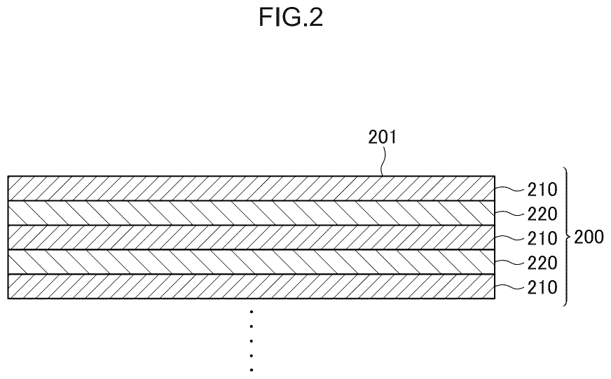

FIG. 2 shows a cross-section of the portion A of FIG. 1, i.e., an enlarged view of configuration of a portion of the protective film 200 in the vicinity of the surface 201. As shown in FIG. 2, the protective film 200 has a plurality of the first layers 210 and the second layers 220, and the first layer and the second layer are arranged so that the plurality of the first layers 210 and the second layers 220 are alternately aligned along a direction perpendicular to the surface 201 of the protective film 200. The direction perpendicular to the surface 201 is hereinafter also referred to as the “depth direction”. The first layer 210 and the second layer 220 are both layers containing yttrium oxide.

The first layer 210 is a layer containing Y2O3 as a main component. The first layer 210 may contain only Y2O3, but may also contain a component in addition to Y2O3 as an additive.

The second layer 220 is a layer containing YO as a main component. The second layer 220 may contain only YO, but may also contain a component in addition to YO as an additive. Such a second layer 220 can be said to be a layer that contains all of elements contained in the first layer 210 and that is different from the first layer in composition ratio of each element. The “element contained in the first layer 210” is “Y” or “O” in the present embodiment, and when the additive is contained, the element refers to the constituent element of the additive.

The first layer 210 containing Y2O3 as the main component, in which the composition ratio of Y and O is stoichiometric, is therefore a relatively stable layer and has low reactivity to plasma. In other words, it has high durability against plasma. On the other hand, the second layer 220 containing YO as a main component, in which the composition ratio of Y and O is not stoichiometric, is thereby a relatively unstable layer and has high reactivity to plasma than the first layer 210. In other words, it has low durability against plasma.

The boundary between the first layer 210 and the second layer 220 may not be as clear as shown in FIG. 2. In other words, the composition ratio of Y and O may vary discontinuously (i.e., stepwise) or continuously (i.e., smoothly) as a position in the depth direction changes. The first layer 210 and the second layer 220 may also be alternately aligned in the entire protective film 200 along the depth direction; however, they may be alternately aligned only in a portion of the protective film 200 in the vicinity of the surface 201.

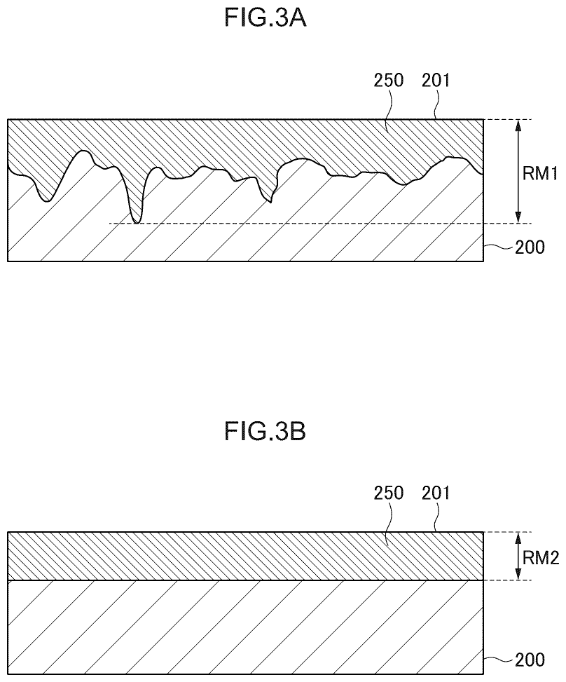

An effect of the protective film 200 having the multilayer structure as described above will be explained. FIG. 3A shows a cross-section of the protective film 200 according to a comparative example. In the comparative example, the protective film 200 does not have a multilayer structure as in the present embodiment, but is entirely composed of a single layer containing Y2O3 as a main component. In the same figure, the region marked with a sign “250” and with different hatching represents a region deteriorated by exposure to plasma. The region is also referred to as a “deteriorated region 250” below.

As shown in the comparative example, in a structural member with a conventional configuration, the depth of the deteriorated portion of the protective film 200 was not uniform within the plane thereof. In other words, in each portion of the surface 201, the depth of the deteriorated region 250 varied greatly from place to place.

The deteriorated protective film 200 would arise as a source of particles. Therefore, after the deterioration of the protective film 200 has proceeded to a certain degree, when the deteriorated region 250 on a surface layer of the protective film 200 is removed by polishing or the like to expose a new, undeteriorated surface, the structural member 10 can continue to be used.

In this case, in order to leave no deteriorated region 250, it is necessary to perform polishing to the deepest position of the deteriorated region 250. For example, in an example in FIG. 3A, the entire range indicated by “RM1” needs to be removed by polishing. As the protective film 200 is removed to a deep position each time, the protective film 200 is made thin in a relatively short period of time, thereby necessitating exchange of the structural member 10 to a new member.

The RM1 also includes a portion of the protective film 200 that has not been deteriorated. In other words, as a result of setting the amount of removal according to the most deeply deteriorated portion, an undeteriorated portion of the protective film 200 will also be removed in other portions.

Therefore, as described above, the protective film 200 has a multilayer structure with the first layer 210 and the second layer 220 alternately stacked in the present embodiment. In such a configuration, the deterioration of the protective film 200 is more likely to proceed in the direction parallel to the interface of each layer than in the depth direction. In addition, as the deterioration proceeds more slowly in the depth direction, the in-plane variation in depth of the deteriorated portions becomes smaller.

FIG. 3B shows a cross-section of the protective film 200 according to the present embodiment in the same manner as FIG. 3A. It is noted that in FIG. 3B, the division of the first layer 210 and the second layer 220 is omitted. In FIG. 3B, the deteriorated region 250 is also shown after exposure to plasma, as in FIG. 3A.

In the protective film 200 according to the present embodiment, the deterioration is likely to proceed in the direction parallel to the surface 201. Therefore, as shown in FIG. 3B, the depth of the deteriorated region 250 developed by exposure to plasma is mostly equal to that of each portion along the surface 201. Inhibiting the deterioration in the depth direction from proceeding also allows the depth of the deepest portion of the deteriorated region 250 to be shallower than in the case of the comparative example shown in FIG. 3A. In many cases, the position of the bottom edge of the deteriorated region 250 is the same as the position of any of the second layers 220.

In the example shown in FIG. 3B, in order to continue using the structural member 10, it is necessary to remove the entire range indicated by “RM2” by polishing. Unlike the comparative example in FIG. 3A, the RM2 to be removed includes almost no portion of the protective film 200 that has not been deteriorated.

In the protective film 200 of the present embodiment, the deterioration toward the depth direction proceeds slower as described above, so that a surface layer of the protective film 200 can be less frequently removed, thereby enabling use of the structural member 10 for a long period of time. It is also not necessary to remove the protective film 200 to a deep position each time, so that the structural member 10 can be used for an even longer period of time.

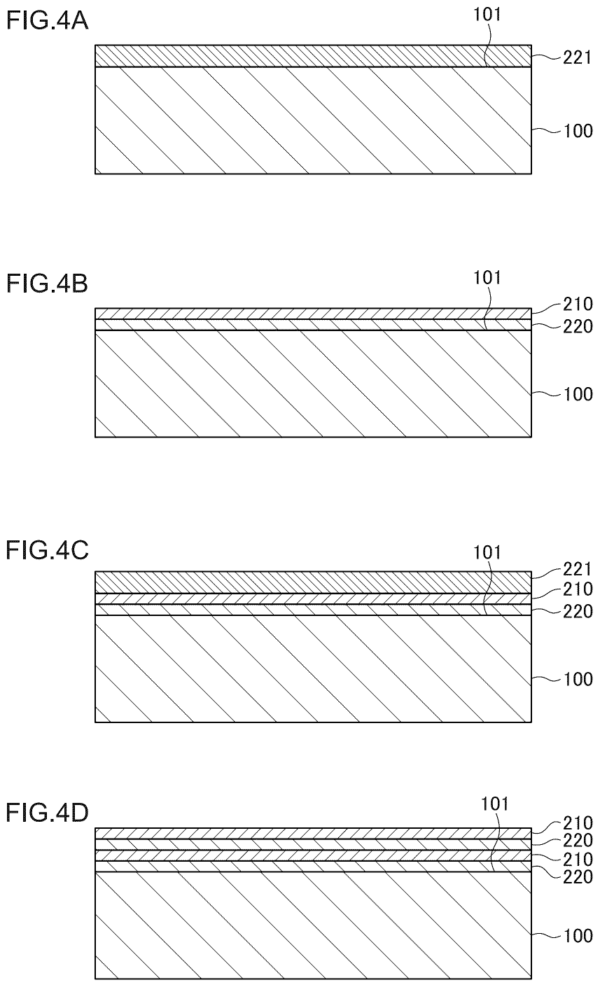

A method for producing the structural member 10 will be described with reference to FIG. 4A to FIG. 4D. First, a base material 100 is provided. It is preferable that the surface 101 of the base material 100 has been preliminarily adjusted for surface roughness thereof, and the like to the extent that the protective film 200 can be stably formed thereafter.

Thereafter, as shown in FIG. 4A, a metal layer 221 is then formed so as to cover the surface 101 of the base material 100. The metal layer 221 is a layer mainly composed of yttrium (Y). Such a metal layer 221 can be formed, for example, by a physical vapor deposition method using yttrium as a metal target, but may also be formed by other deposition methods.

Then, oxygen plasma is generated in the vicinity of the metal layer 221, and the plasma reacts with the metal layer 221. As a result, a portion of the metal layer 221 on the surface side thereof (the side opposite to the base material 100) is oxidized and most of the portion is converted to Y2O3. In other words, the portion on the surface side of the metal layer 221 becomes the first layer 210 as shown in FIG. 4B.

Assuming that the metal layer 221 is exposed to oxygen plasma for a sufficient time, the entire portion thereof will be converted to the first layer 210 (Y2O3). However, in the present embodiment, at a point of time before the entire metal layer 221 is converted to the first layer 210 (Y2O3), oxygen supply is stopped or reduced. Therefore, a portion of the metal layer 221 on the base material 100 side is not fully oxidized and is mostly converted to YO. Accordingly, the portion of the metal layer 221 on the base material 100 side becomes the second layer 220 as shown in FIG. 4B.

As described above, the portion that was the metal layer 221 in FIG. 4A is converted to the first layer 210 and the second layer 220 via the oxidation step in FIG. 4B. Allowing for changes in composition ratio of Y and O at the boundary between the two layers desirably can be adjusted according to the amount of oxygen supplied, an output of the plasma, and the like.

Subsequently, as shown in FIG. 4C, the metal layer 221 is formed again so as to cover the surface of the first layer 210 that was at the outermost surface layer. A method for forming this metal layer 221 is the same as the method for forming the metal layer 221 shown in FIG. 4A. A supply of yttrium from a metal target to the base material 100 may be interrupted during the oxidation step shown in FIG. 4B or it may be continued.

Subsequently, the same oxidation step as in FIG. 4B is carried out again. A portion of the metal layer 221 on the surface side thereof (the side opposite to the base material 100), shown in FIG. 4C, is oxidized and is converted to the first layer 210 as shown in FIG. 4D. A portion of the metal layer 221 on the base material 100 side is not sufficiently oxidized and is converted to the second layer 220 as shown in FIG. 4D.

Hereinafter, the step of forming the metal layer 221 on a surface and the step of oxidizing the metal layer 221 to form the first layer 210 and the second layer 220 are repeatedly carried out in the same manner. As a result, a plurality of first layers 210 and second layers 220 are stacked to form the protective film 200 shown in FIG. 2.

The first layer 210 and the second layer 220 both contain yttrium oxide and are different from each other in composition ratio of yttrium and oxygen. Therefore, in forming the first layer 210 and the second layer 220 so that they are aligned alternately, it is not necessary to switch a target or gas species in the course of the process, but only to change the deposition conditions, such as the amount supplied.

In the present embodiment, the first layer 210 is more exposed on the surface 201 of the protective film 200. With the highly durable first layer 210 formed as a surface of the protective film 200, the performance of the protective film 200 can be enhanced.

After the first layer 210 that was the outermost surface layer was deteriorated, the second layer 220 that is located further in depth from the first layer, is deteriorated. Since the second layer 220 is a layer susceptible to deterioration, the deterioration is unlikely to proceed further in depth until the entire second layer 220 is deteriorated. As a result, localized deep deterioration is less likely to occur.

As an alternative to such an embodiment, a configuration such that the second layer 220 is more exposed on the surface 201 of the protective film 200, may be adopted.

When the less durable second layer 220 is intentionally exposed on the surface, light elements such as Na and Ca attached to the surface 201 of the protective film 200 can be detached and removed together with the outermost second layer 220 in seasoning prior to start of processing of a semiconductor manufacturing apparatus. This enables starting processing such as etching with a (new) surface of the protective film 200 clean.

In order to expose the second layer 220 more at the surface 201 of the protective film 200, after the protective film 200 was formed by the method shown in FIG. 4, the first layer 210 at the outermost surface layer may be removed by polishing or the like.

So far, the present embodiments have been described with reference to specific examples. However, the present disclosure is not limited to these specific examples. Design changes appropriately made to these specific examples by those skilled in the art are also included in the scope of the present disclosure as long as they include the features of the present disclosure. Each element included in each of the aforementioned specific examples, as well as their arrangement, conditions, shapes, and the like, are not limited to those exemplified, and can be appropriately changed. Each element included in each of the aforementioned specific examples can be appropriately combined as long as no technical inconsistency thereof results.

What is claimed is:

1. A structural member comprising a base material and a protective film covering a surface of the base material,
wherein at least a portion of the protective film in the vicinity of a surface thereof has a first layer and a second layer that comprises all of elements comprised in the first layer and that is different from the first layer in composition ratio of each element,
wherein the first layer and the second layer are alternately aligned along a depth direction perpendicular to the surface of the protective film.

2. The structural member according to claim 1, wherein the first layer has higher durability against plasma than the second layer, and
the first layer is exposed on a surface of the protective film.

3. The structural member according to claim 1, wherein the first layer has higher durability against plasma than the second layer, and
the second layer is exposed on a surface of the protective film.

4. The structural member according to claim 2, wherein the first layer and the second layer both comprise yttrium oxide and are different from each other in composition ratio of yttrium and oxygen.

5. The structural member according to claim 3, wherein the first layer and the second layer both comprise yttrium oxide and are different from each other in composition ratio of yttrium and oxygen.
